(19) United States
(12) Patent Application Publication
(10) Pub. No.: US 2019/0267229 A1
(43) Pub. Date: Aug. 29, 2019

(54) SEMICONDUCTOR DEVICE AND METHOD OF MANUFACTURING THE SAME

(71) Applicant: TOSHIBA MEMORY CORPORATION, Tokyo (JP)

(72) Inventors: Tatsunori ISOGAI, Yokkaichi Mie (JP); Masaki NOGUCHI, Yokkaichi Mie (JP)

(73) Assignee: TOSHIBA MEMORY CORPORATION, Tokyo (JP)

(21) Appl. No.: 16/113,992

(22) Filed: Aug. 27, 2018

(30) Foreign Application Priority Data
Feb. 28, 2018 (JP) 2018-035294

(51) Int. Cl. H01L 21/02; H01L 21/3213; H01L 21/8238; H01L 27/092; H01L 21/28

(52) U.S. Cl. CPC H01L 21/0214; H01L 21/32139; H01L 21/823814; H01L 29/0653; H01L 27/092; H01L 21/28247; H01L 21/823864

(57) ABSTRACT

A semiconductor device has a substrate. An insulating film is provided on the substrate. An electrode is provided on the insulating film. A first silicon nitride film is provided on an upper surface of the electrode. A second silicon nitride film is provided on the first silicon nitride film and has a higher oxygen concentration than the first silicon nitride film.

### CROSS-REFERENCE TO RELATED APPLICATION

This application is based upon and claims the benefit of priority from Japanese Patent Application No. 2018-035294, filed Feb. 28, 2018, the entire contents of which are incorporated herein by reference.

### FIELD

Embodiments disclosed herein relate to a semiconductor device and a method of manufacturing the same.

### BACKGROUND

Since a silicon nitride film is denser than a silicon oxide film and has better etching resistance than the silicon oxide film, the silicon nitride film is used as an etch stop film, a hard mask, a protective film, a stress applying film, and the like in a process of manufacturing a complementary metal oxide semiconductor (CMOS) transistor.

### DESCRIPTION OF THE DRAWINGS

FIG. 1 is a cross-sectional view illustrating an example arrangement of a semiconductor device 1 according to a first embodiment.

FIGS. 2A to 2C are composition diagrams illustrating a bond between nitrogen (N) and hydrogen (H) and a back bond of nitrogen in a silicon nitride film.

FIG. 3 is a cross-sectional view illustrating an example of a method of manufacturing the semiconductor device according to the first embodiment.

FIG. 4 is a cross-sectional view illustrating an example of the method of manufacturing the semiconductor device subsequent to FIG. 3.

FIG. 5 is a cross-sectional view illustrating an example of the method of manufacturing the semiconductor device subsequent to FIG. 4.

FIG. 6 is a cross-sectional view illustrating an example of the method of manufacturing the semiconductor device subsequent to FIG. 5.

FIG. 7 is a cross-sectional view illustrating an example of the method of manufacturing the semiconductor device subsequent to FIG. 6.

FIG. 8 is a cross-sectional view illustrating an example arrangement of a semiconductor device according to a second embodiment.

FIGS. 9A and 9B are views illustrating characteristics of an upper hard mask according to a third embodiment.

FIGS. 10A and 10B are views illustrating a method of manufacturing the semiconductor device according to the third embodiment.

### DETAILED DESCRIPTION

Provided are a semiconductor device capable of reducing hydrogen diffused from a silicon nitride film and a method of manufacturing the semiconductor device.

A semiconductor device according to some embodiments has a semiconductor substrate. Agate insulating film is provided on the semiconductor substrate. Agate electrode is provided on the gate insulating film. A first silicon nitride film is provided on an upper surface of the gate electrode. A second silicon nitride film is provided on the first silicon nitride film and has a higher oxygen concentration than the first silicon nitride film.

Hereinafter, embodiments of the present disclosure will be described with reference to the drawings. The present embodiments do not limit the present disclosure. In the following embodiments, a vertical direction of a semiconductor substrate represents a relative direction when a surface on which a semiconductor element is provided is directed upward, and in some instances, the vertical direction of the semiconductor substrate differs from a vertical direction defined in accordance with gravitational acceleration. The drawings are schematic or conceptual, and the ratios between portions and the like are not necessarily the same as the actual values thereof. In the specification and the drawings, the same elements, which have been previously described with reference to the previous drawings, are marked with the same reference numerals, and a detailed description thereof will be appropriately omitted.

### First Embodiment

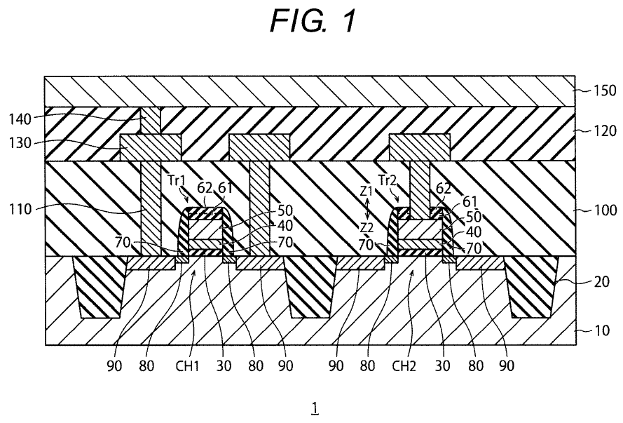

FIG. 1 is a cross-sectional view illustrating an example arrangement of a semiconductor device 1 according to a first embodiment. For example, the semiconductor device 1 may be an NAND type electrically erasable programmable read-only memory (EEPROM). For example, the NAND type EEPROM has a three-dimensional memory cell array (not illustrated) having a three-dimensional structure, and a drive circuit or a peripheral circuit provided on the same substrate as the memory cell array so as to drive the memory cell array. For example, the drive circuit or the peripheral circuit includes a planar MOS transistor. In addition, FIG. 1 illustrates two transistors Tr1 and Tr2 as the planar MOS transistor. However, actually, multiple transistors are provided.

The semiconductor device 1 has a semiconductor substrate 10, element isolating portions 20, gate insulating films 30, lower gate electrodes 40, upper gate electrodes 50, lower hard masks 61, upper hard masks 62, sidewall films 70, extension layers 80, source-drain layers 90, interlayer insulating films 100 and 120, contact plugs 110 and 140, and wiring layers 130 and 150.

The semiconductor substrate 10 is, for example, a silicon monocrystalline substrate having a plane orientation (100). For example, the semiconductor substrate 10 may be a Ge substrate, a SiGe substrate, a SiC substrate, a GaAs substrate, or the like. In addition, the semiconductor substrate 10 may be a silicon-on-insulator (SOI) substrate.

The element isolating portion 20 is provided within a surface region of the semiconductor substrate 10 and electrically isolates adjacent active areas. For example, the element isolating portion 20 is shallow trench isolation (STI).

The gate insulating film 30 is provided on the semiconductor substrate 10. For example, a high dielectric material, such as a silicon oxide film, a silicon oxynitride film, or hafnia, having a relative dielectric constant higher than a relative dielectric constant of a silicon oxide film is used for the gate insulating film 30.

The lower gate electrode 40 is provided on the gate insulating film 30, and the upper gate electrode 50 is provided on the gate electrode 40. For example, doped polysilicon is used for the lower gate electrode 40. For example, metal or metal silicide is used for the upper gate electrode 50. Metal used for the upper gate electrode 50 is, for example, low-resistance metal such as tungsten. The metal silicide is, for example, tungsten silicide or the like. As described above, the gate electrodes 40 and 50 according to the present embodiment has a bilayer structure, and at least the upper gate electrode 50 is made of metal or metal silicide. Therefore, it is possible to reduce gate resistance.

In a case in which each of the transistors Tr1 and Tr2 is a p-type MOS transistor, the lower gate electrode 40 includes a p-type impurity such as, for example, boron in order to adjust threshold voltage of the transistors Tr1 and Tr2. In a case in which each of the transistors Tr1 and Tr2 is an n-type MOS transistor, the lower gate electrode 40 includes an n-type impurity such as, for example, phosphorus or arsenic in order to adjust threshold voltage of the transistors Tr1 and Tr2.

The hard masks 61 and 62 are provided on the upper gate electrode 50. For example, a silicon nitride film is used for the hard masks 61 and 62. The lower hard mask 61, as a first silicon nitride film, is provided on an upper surface of the upper gate electrode 50 and has a comparatively low oxygen concentration. The upper hard mask 62, as a second silicon nitride film, is provided on the lower hard mask 61 and has a higher oxygen concentration than the lower hard mask 61. For example, the lower hard mask 61 has an oxygen concentration of approximately 0%. The upper hard mask 62 has an oxygen concentration of 1% to 10%. The oxygen concentration of the upper hard mask 62 is determined in consideration of heat resistance and hydrogen barrier performances required for the silicon nitride film. In consideration of the heat resistance and the hydrogen barrier performances, the oxygen concentration of the silicon nitride film used for the hard mask 62 may range from about 0.1% to about 30%. Further, a film forming rate is decreased in a case in which the silicon nitride film is formed by using an LP-CVD method and adding an oxygen-based gas. For this reason, in consideration of productivity, the oxygen concentration of the silicon nitride film used for the hard mask 62 may range from about 1% to about 10%.

The sidewall film 70, as a third silicon nitride film, is provided on side surfaces of the gate electrodes 40 and 50 and the hard masks 61 and 62, and similar to the upper hard mask 62, the sidewall film 70 has a higher oxygen concentration than the lower hard mask 61. For example, the sidewall film 70 has an oxygen concentration of about 1% to about 10%.

The extension layer 80 is provided on a surface of the semiconductor substrate 10 from a portion directly under an end of the gate electrode 40 to the source-drain layer 90. The extension layer 80 is of the same conductivity type (p-type or n-type) as the source-drain layer 90 adjacent to the extension layer 80, and the extension layer 80 is shallower and has a lower impurity concentration than the source-drain layer 90. Channel regions CH1 and CH2 of the transistors Tr1 and Tr2 are present between the extension layers 80 (i.e., under the gate electrodes 40 and 50) at both sides of the gate electrodes 40 and 50. As the channel regions CH1 and CH2 are reversed by gate voltage, the extension layers 80 at both sides of the channel regions CH1 and CH2 are electrically connected. Therefore, the transistors Tr1 and Tr2 are turned on.

The source-drain layers 90 are provided on the surface of the semiconductor substrate 10 at both sides of the gate electrodes 40 and 50. The source-drain layer 90 is connected to the extension layer 80 adjacent to the source-drain layer 90 and has a higher impurity concentration than the extension layer 80. Therefore, the source-drain layer 90 is electrically connected, with low resistance, between the contact plug 110 and the extension layer 80.

The interlayer insulating film 100 covers and protects the semiconductor substrate 10, the gate electrode 40, and the like. For example, an insulating film such as a silicon oxide film is used for the interlayer insulating film 100.

The contact plug 110 is provided in the interlayer insulating film 100 and electrically connected to the source-drain layer 90 or the upper gate electrode 50. For example, low-resistance metal such as copper or tungsten is used for the contact plug 110.

The interlayer insulating film 120 is provided on the interlayer insulating film 100. For example, an insulating film such as a silicon oxide film is used for the interlayer insulating film 120.

The wiring layer 130 and the contact plug 140 are provided in the interlayer insulating film 120. The wiring layer 130 is provided on the contact plug 110, and the contact plug 140 is provided on the wiring layer 130. Further, the wiring layer 150 is provided on the contact plug 140. As described above, the contact plugs 110 and 140, the wiring layers 130 and 150, and the interlayer insulating films 100 and 120 constitute a multilayered wiring structure. With the multilayered wiring structure, the transistors Tr1 and Tr2 serve as a drive circuit or a peripheral circuit for the memory cell array (not illustrated) provided on the multilayered wiring structure. The memory cell array may be provided above the transistors Tr1 and Tr2 or may be provided within a region of the semiconductor substrate 10 different from the transistors Tr1 and Tr2.

The hard masks 61 and 62 are provided on an upper surface of the upper gate electrode 50 of the semiconductor device 1 according to the some embodiments. The hard mask 62 has a higher oxygen concentration than the hard mask 61. Therefore, a hydrogen component contained in the hard mask 62 remains in the hard mask 62 and is hardly diffused. Hereinafter, the reason will be described.

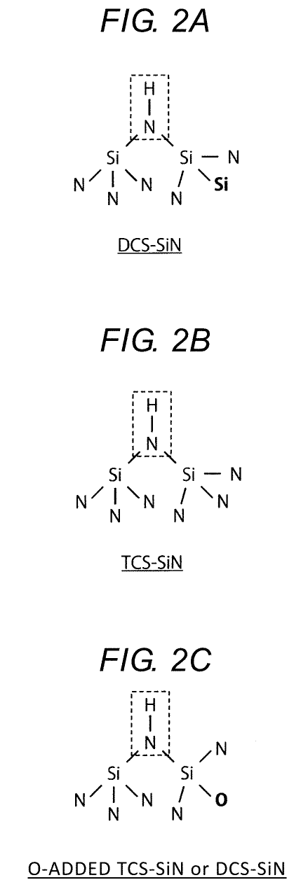

FIGS. 2A to 2C are composition diagrams illustrating a bond between nitrogen (N) and hydrogen (H) and a back bond of nitrogen in a silicon nitride film. FIG. 2A illustrates a composition of a silicon nitride film (hereinafter, referred to as a DCS-SiN film) formed by using dichlorosilane (DCS) (SiH₂Cl₂). FIG. 2B illustrates a composition of a silicon nitride film (hereinafter, referred to as a TCS-SiN film) formed by using tetrachlorosilane (TCS) (SiCl₄). FIG. 2C illustrates a composition of a film (hereinafter, referred to as a DCS-SiN (O) film or a TCS-SiN (O) film) formed by adding oxygen into the DCS-SiN film or the TCS-SiN film. Further, FIG. 2C illustrates that the DCS-SiN (O) film and the TCS-SiN (O) film have the same structure, but it is considered that the DCS-SiN (O) film has a large number of Si-Si bonds in comparison with the TCS-SiN (O) film.

The frame with a broken line indicates a bond between nitrogen and hydrogen (N-H bond). As described above, the silicon nitride film includes not a little hydrogen. Even in any one of the DCS-SiN film and the TCS-SiN film, the hydrogen content is not greatly changed. However, the present inventors have conducted diligent research and discovered that bonding force (bonding energy) between hydrogen and nitrogen is changed by a back bond other than the bond between hydrogen and nitrogen.

For example, the back bond of the DCS-SiN film in FIG. 2A includes a bond between silicon and silicon (Si-Si bond) in addition to a bond between silicon and nitrogen (Si-N bond). The back bond of the TCS-SiN film in FIG. 2B mostly has the bond between silicon and nitrogen (Si-N bond), and a degree of the bond between silicon and silicon (Si-Si bond) is lower in the TCS-SiN film than in the DCS-SiN film. That is, the TCS-SiN film has a larger number of bonds between silicon and nitrogen (Si-N bond) than the DCS-SiN film.

Here, because the DCS-SiN film including a large amount of silicon in the back bond includes a large number of bonds between silicon and silicon (Si-Si bond) of the same type, polarization is comparatively low. Meanwhile, because the TCS-SiN film including a large amount of nitrogen in the back bond includes a large number of bonds between elements of different types (Si-N bond), polarization is comparatively high. The present inventors have discovered that the higher the polarization caused by the back bond, the greater the bonding force of the N-H bond in the frame with the broken line. That is, the TCS-SiN film is more strongly bonded to hydrogen in comparison with the DCS-SiN film, and the TCS-SiN film does not generate hydrogen as much as the DCS-SiN film even though the TCS-SiN film is subjected to a heat treatment. In other words, the TCS-SiN film has better heat resistance than the DCS-SiN film.

Oxygen is contained in the back bond of the DCS-SiN(O) film in FIG. 2C. Electronegativity is increased in the order of silicon, nitrogen, and oxygen. Therefore, it can be seen that in comparison with the DCS-SiN film, the DCS-SiN (O) film containing oxygen in the back bond has greater polarization and has greater bonding force of the N-H bond in the frame with the broken line. That is, the DCS-SiN(O) film in FIG. 2C is more strongly bonded to hydrogen in comparison with the DCS-SiN film in FIG. 2A, and the DCS-SiN(O) film does not generate hydrogen as much as the DCS-SiN film even though the DCS-SiN(O) film is subjected to a heat treatment. In other words, the SiN film may have a structure with better heat resistance by adding oxygen O. Further, while the DCS-SiN film has been described as an example, the type of film is not limited to the DCS-SiN film, and the heat resistance may be obtained by adding oxygen O as long as the film is the SiN film.

Hydrogen contained in the upper hard mask 62 is hardly diffused in the case in which the SiN film, which has a comparatively high oxygen concentration as oxygen is added, is used for the upper hard mask 62 according to some embodiments. Meanwhile, the lower hard mask 61 is in contact with the upper gate electrode 50 made of metal or metal silicide. Therefore, if the SiN film having a high oxygen concentration is used for the lower hard mask 61, metal of the upper gate electrode 50 is exposed to an oxidative gas from the SiN film during a heat treatment and oxidized. If the upper gate electrode 50 is oxidized, gate resistance is increased. In addition, there is concern that whiskers are formed due to the oxidation of metal of the upper gate electrode 50 and the upper gate electrode 50 is deformed. Therefore, the TCS-SiN film having a low oxygen content may be used for the lower hard mask 61.

As described above, the hard mask according to some embodiments has a bilayer structure including the lower hard mask 61 and the upper hard mask 62. The TCS-SiN film having a low oxygen content is used for the lower hard mask 61 to inhibit the oxidation of the upper gate electrode 50, and the SiN film having a comparative high oxygen content is used for the upper hard mask 62 to inhibit the diffusion of hydrogen.

The concentration of oxygen in the upper hard mask 62 may be about 1% to about 10%. In addition, a film thickness of the lower hard mask 61 may be set to such an extent as to inhibit the oxidation of the upper gate electrode 50, and for example, the lower hard mask 61 has a film thickness of several nanometers (nm).

In the case in which the SiN film having a comparatively high oxygen concentration is used for the sidewall film 70, hydrogen contained in the sidewall film 70 is hardly diffused to the outside of the sidewall film 70. In addition, since the SiN film having a comparatively high oxygen concentration is used for the sidewall film 70, it is possible to inhibit hydrogen from being introduced into the transistors Tr1 and Tr2 from the outside.

Since the SiN film having a comparatively high oxygen concentration is used for both of the upper hard mask 62 and the sidewall film 70, it is possible to inhibit the diffusion of hydrogen contained in the upper hard mask 62 and the sidewall film 70 and to rigidly inhibit hydrogen from being introduced into the transistors Tr1 and Tr2 from the outside.

Each of the transistors Tr1 and Tr2 may be a p-type MOS transistor. The p-type MOS transistor has a p-type extension layer 80, a p-type source-drain layer 90, and a p-type lower gate electrode 40. For example, the extension layer 80, the source-drain layer 90, and the lower gate electrode 40 contain boron as a p-type impurity. In this case, when hydrogen is diffused to the gate insulating film 30, the hydrogen cuts the bond between silicon and oxygen in the gate insulating film 30. The boron in the lower gate electrode 40 is introduced into a channel region through a cut portion between silicon and oxygen and changes threshold voltage. Alternatively, when hydrogen is diffused to the source-drain layer 90, the hydrogen is bonded with boron and deactivates the source-drain layer 90.

In contrast, according to some embodiments, the hard mask 62 is formed by the comparative dense TCS-SiN film, and the upper hard mask 62 and the sidewall film 70 are formed thereon by the SiN film which further includes oxygen. Therefore, it is possible to inhibit hydrogen from being diffused or introduced into the channel regions CH1 and CH2 or the source-drain layer 90. As a result, it is possible to inhibit irregularity of the threshold voltage of the transistors Tr1 and Tr2 and to inhibit an increase in resistance of the source-drain layer 90. This result leads to stabilization of the operation of the drive circuit (peripheral circuit) of the memory cell array. In addition, during a heat treatment in a process of manufacturing the memory cell array, it is possible to use a sufficiently high temperature of, for example, 1,000° C. or more.

Next, a method of manufacturing the semiconductor device 1 according to the first embodiment will be described. Here, the TCS-SiN(O) film has been described as an example of the SiN film containing a comparatively larger amount of oxygen, but a DCS-SiN(O) film may be formed by changing a Si source gas.

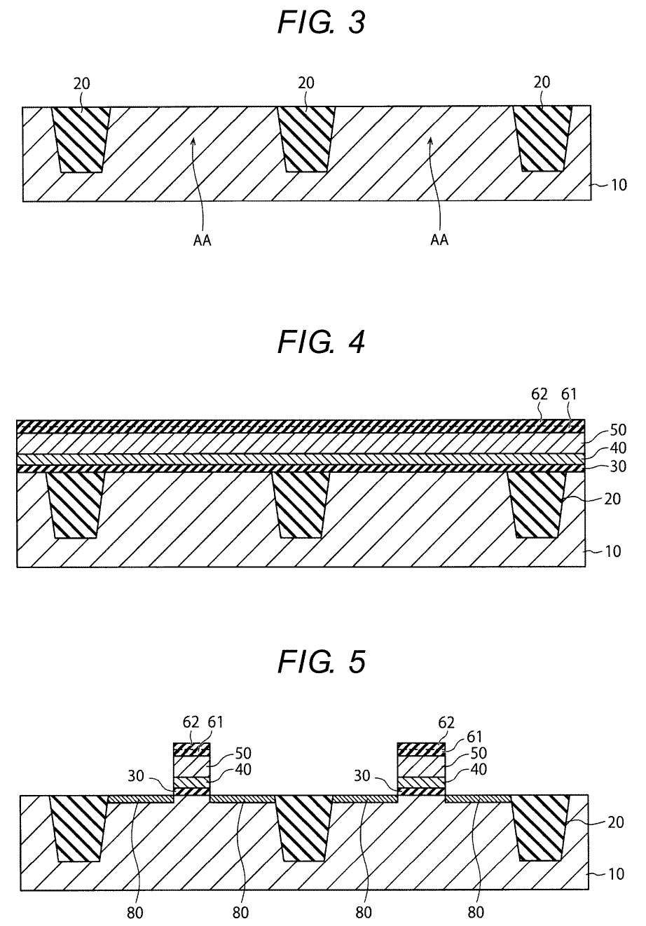

FIGS. 3 to 7 are cross-sectional views illustrating an example of the method of manufacturing the semiconductor device 1 according to the first embodiment. First, a trench is formed in an element isolation area of the semiconductor substrate by using a lithography technology and a dry etching technology. Next, the trench is charged with an insulating film such as a silicon oxide film and flattened by using a chemical mechanical polishing (CMP) method. Therefore, the element isolating portion 20 illustrated in FIG. 3 is formed. The element isolating portion 20 defines active areas AA and electrically isolates the adjacent active areas AA.

Next, as illustrated in FIG. 4, the gate insulating film 30 such as a silicon oxide film is formed on the semiconductor substrate 10 by using a thermal oxidation method or a plasma oxidation method. The gate insulating film 30 may be a high dielectric (high-k) film, such as a silicon oxynitride film or hafnia, as well as the silicon oxide film.

Next, a material of the lower gate electrode 40 is deposited on the gate insulating film 30. The material of the lower gate electrode 40 may be, for example, a semiconductor such as doped polysilicon. The doped polysilicon is formed by depositing polysilicon, introducing an n-type or p-type impurity into the polysilicon by ion implantation, and then activating the impurity through a heat treatment. Alternatively, the n-type or p-type impurity may be added to the doped polysilicon when depositing the polysilicon. For example, a gate electrode of the p-type MOS transistor includes p-type doped polysilicon. A gate electrode of the n-type MOS transistor includes n-type doped polysilicon.

Next, a low-resistance metal film such as, for example, tungsten, as a material of the upper gate electrode 50, is formed on the material of the lower gate electrode 40. To inhibit an interface reaction between the lower gate electrode 40 and the upper gate electrode 50, a barrier metal may be provided between the lower gate electrode 40 and the upper gate electrode 50. For example, tungsten nitride, titanium nitride, or the like is used for the barrier metal. A film thickness of each of the lower gate electrode 40 and the upper gate electrode 50 is, for example, 50 nm to 100 nm.

The material of the upper gate electrode 50 may be, for example, metal silicide such as tungsten silicide. In a case in which the metal silicide is formed, a metal film such as tungsten may be formed on doped polysilicon, and the doped polysilicon and the metal may be reacted by a heat treatment. Therefore, the metal silicide, as the upper gate electrode 50, is formed on the doped polysilicon as the lower gate electrode 40.

Next, the materials of the hard masks 61 and 62 are formed on the material of the upper gate electrode 50 by using a low-pressure chemical vapor deposition (LP-CVD) method or a plasma-enhanced CVD (PE-CVD) method. The silicon nitride film, which has resistance against dry etching, is used for the materials of the hard masks 61 and 62. For example, the silicon nitride film may be formed by adding nitride gas such as ammonia (NH₃) to a silicon source such as silane (SiH₄), dichlorosilane (SiH₂Cl₂), or tetrachlorosilane (SiCl₄) under an ambience of about 650° C. to about 750° C.

For example, a film thickness of the silicon nitride film may be about 20 nm to about 50 nm. The silicon nitride film tends to cause insufficient nitriding and have sufficient silicon as the silicon nitride film is formed at a low temperature. As described above, this configuration decreases bonding force of the N-H bond in the silicon nitride film. Therefore, it is preferred that a film forming temperature is high. In addition, the silicon nitride film using tetrachlorosilane (TCS) becomes a nitrogen-rich film in comparison with the silicon nitride film using silane or dichlorosilane (DCS). In comparison with the silicon-rich silicon nitride film, the nitrogen-rich silicon nitride film has high bonding force of the N-H bond and hardly emits hydrogen at a high temperature. Therefore, in some embodiments, it is preferred that the silicon nitride film is a TCS-SiN film formed by using TCS.

Next, oxygen is introduced into the silicon nitride film by using an ion implantation method. In this case, oxygen is introduced into an upper portion of the silicon nitride film but not introduced into a lower portion of the silicon nitride film. For example, oxygen ions are implanted with acceleration energy of about 10 keV and at a dose amount of about 1E16cm:⁻². After oxygen is introduced, the silicon nitride film is subjected to a heat treatment at about 900° C. to about 1,000° C. Therefore, the lower hard mask 61 and the upper hard mask 62 are formed. The upper hard mask 62 has an oxygen concentration of, for example, about 1% to about 10%, and the lower hard mask 61 has an oxygen concentration of, for example, almost 0%. The lower hard mask 61 is thinner in thickness than the upper hard mask 62, and for example, the lower hard mask 61 has a thickness of several nanometers (nm). As the upper hard mask 62 contains oxygen, the upper hard mask 62 becomes a TCS-SiN(O) film. Therefore, the upper hard mask 62 has higher bonding force of the N-H bond in the silicon nitride film and hardly emits hydrogen at a high temperature. Meanwhile, the lower hard mask 61 becomes the TCS-SiN film which rarely includes oxygen. Therefore, it is possible to inhibit the oxidation of the metal of the upper gate electrode 50. As described above, in the present embodiment, the hard masks 61 and 62 have the bilayer structure, and as a result, it is possible to achieve both of the inhibition of the diffusion of hydrogen and the inhibition of the oxidation of metal.

In general, the silicon nitride film formed by using the LP-CVD method or the PE-CVD method includes hydrogen of 1E21cm⁻³ to 1E22cm⁻³. There is concern that in a subsequent process, hydrogen in the silicon nitride film may be emitted from the silicon nitride film by, for example, a heat treatment at a high temperature of 800° C. or more. In contrast, in the present embodiment, as described below, a TCS-SiN film is used for the silicon nitride film, and the TCS-SiN(O) film is made by introducing oxygen. Therefore, it is possible to inhibit the emission of hydrogen even by heat-treating the silicon nitride film at, for example, 1,000° C. or higher.

In the present embodiment, the ion implantation method is used to introduce oxygen into the upper hard mask 62. However, oxygen may be added at the time of forming the silicon nitride film to introduce oxygen into the upper hard mask 62. In this case, at the time of forming the lower hard mask 61, the silicon nitride film is formed by, for example, adding nitride gas such as ammonia (NH₃) into a silicon source such as tetrachlorosilane (SiCl₄). Thereafter, at the time of forming the upper hard mask 62, the silicon nitride film may be formed by, for example, adding nitride gas such as ammonia (NH₃) and oxidative gas such as a minuscule amount of oxygen (O₂) or dinitrogen monoxide (N₂O) into a silicon source such as tetrachlorosilane (SiCl₄). In this case, film forming pressure may be 0.5 Torr or less, and a ratio between gas flow rates of the silicon source, the nitride gas, and the oxidative gas may be, for example, Silicon Source:Nitride Gas:Oxidative Gas=1:10:0.5. As described above, the hard masks 61 and 62 having the bilayer structure may also be formed by adding oxygen during the process of forming the silicon nitride film. Therefore, the structure illustrated in FIG. 4 is obtained.

Next, as illustrated in FIG. 5, the hard masks 61 and 62 are processed in accordance with patterns of the gate electrodes of the transistors Tr1 and Tr2 by using a lithography technology and an etching technology. Next, the materials of the gate electrodes 40 and 50 are processed by using the etching technology by using the hard masks 61 and 62 as masks. In this case, the upper hard mask 62 is etched to a certain degree, but the upper hard mask 62 remains on the upper gate electrode 50.

Next, an impurity is implanted into the surface of the semiconductor substrate 10 by the ion implantation by using the hard masks 61 and 62 and the gate electrodes 40 and 50 as masks. In the case in which the transistors Tr1 and Tr2 are the p-type MOS transistors, the p-type impurity (e.g., boron or boron difluoride) is implanted by the ion implantation. In the case in which the transistors Tr1 and Tr2 are the n-type MOS transistors, the n-type impurity (e.g., arsenic) is implanted by the ion implantation. Therefore, the extension layer 80 is formed. A depth of the extension layer 80 is, for example, about 10 nm.

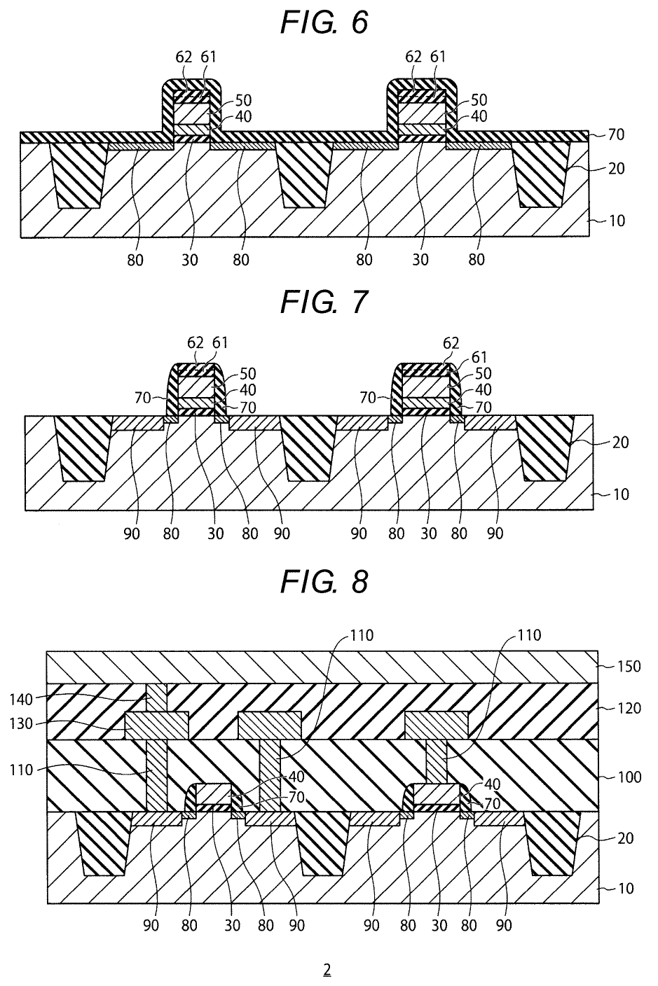

Next, a crystalline state of the surface of the semiconductor substrate 10 is restored by a heat treatment, the extension layer 80 is activated, and then the material of the sidewall film 70 is deposited as the third silicon nitride film as illustrated in FIG. 6. The silicon nitride film is used for the sidewall film 70. In addition, the silicon oxide film (not illustrated) of several nanometers (nm) maybe formed, as a liner layer, between the side surfaces of the gate electrodes 40 and 50 and the sidewall film 70.

The material of the sidewall film 70 may be formed similar to the upper hard mask 62. For example, the material of the sidewall film 70 may be the TCS-SiN(O) film made by implanting oxygen into the TCS-SiN film by the ion implantation or may be the TCS-SiN(O) film deposited by adding oxygen at the time of forming the TCS-SiN film. For example, the material of the sidewall film 70 has an oxygen concentration of about 1% to about 10%.

In a case in which the liner layer is not provided between the side surfaces of the gate electrodes 40 and 50 and the sidewall film 70, the material of the sidewall film 70 may have the bilayer structure, similar to the hard masks 61 and 62, in order to inhibit the oxidation of the upper gate electrode 50. For example, oxygen may not be implanted into the lower portion of the TCS-SiN film as the material of the sidewall film 70, but oxygen may be implanted only into the upper portion of the TCS-SiN film by the ion implantation. Alternatively, the lower portion of the TCS-SiN film may be formed by adding nitride gas such as ammonia (NH₃) into a silicon source such as tetrachlorosilane (SiCl₄), and then, the upper portion of the TCS-SiN film may be formed by, for example, adding nitride gas such as ammonia (NH₃) and oxidative gas such as a minuscule amount of oxygen (O₂) or dinitrogen monoxide (N₂O) into a silicon source such as tetrachlorosilane (SiCl₄). In this case, the material of the sidewall film 70 becomes the silicon nitride film having the bilayer structure including the TCS-SiN film and the TCS-SiN(O) film.

Next, as illustrated in FIG. 7, the material of the sidewall film 70 is etched back by using dry etching. Therefore, the sidewall film 70 remains on the side surfaces of the gate electrodes 40 and 50.

Next, an impurity is implanted into the surface of the semiconductor substrate 10 by the ion implantation by using the sidewall film 70 as a mask. In the case in which the transistors Tr1 and Tr2 are the p-type MOS transistors, the p-type impurity (e.g., boron or boron difluoride) is implanted by the ion implantation. In the case in which the transistors Tr1 and Tr2 are the n-type MOS transistors, the n-type impurity (e.g., phosphorus or arsenic) is implanted by the ion implantation. Therefore, the source-drain layer 90 is formed. A depth of the source-drain layer 90 is greater than a depth of the extension layer 80.

The source-drain layer 90 is activated by a heat treatment, the interlayer insulating film 100 is deposited, and then the contact plug 110 is formed in the interlayer insulating film 100. The wiring layer 130 is formed on the interlayer insulating film 100 and the contact plug 110, and then the interlayer insulating film 120 is formed on the contact plug 110 and the wiring layer 130. The contact plug 140 is formed in the interlayer insulating film 120, and the wiring layer 150 is formed on the contact plug 140. Thereafter, the memory cell array (not illustrated) may be formed above the wiring layer 150 or within another region of the semiconductor substrate 10.

According to some embodiments, the upper hard mask 62 inhibits the diffusion of hydrogen in the upper hard mask 62, and the hard masks 61 and 62 inhibit the introduction of hydrogen from the outside. Therefore, it is possible to inhibit irregularity of threshold voltage of the transistors Tr1 and Tr2 and to inhibit an increase in resistance of the source-drain layer 90. This result leads to stabilization of the operation of the drive circuit or the peripheral circuit of the memory cell array. In addition, during a heat treatment in a process of manufacturing the memory cell array, it is possible to use a sufficiently high temperature.

For example, the silicon nitride film of about 100 nm may be provided, as a cover film (not illustrated), in the multilayered wiring layer of the semiconductor device 1 in order to inhibit hydrogen from the memory cell array from being introduced into the semiconductor device 1. The cover film may also be formed by the SiN film including a comparatively large amount of oxygen. Since the cover film is formed by the SiN film having a comparatively larger amount of oxygen, the cover film may inhibit hydrogen from being introduced into the transistors Tr1 and Tr2 from the memory cell array and may inhibit the diffusion of hydrogen from the silicon nitride film itself. As described below in a third embodiment, the cover film may have an oxygen concentration gradient. Further, the first to third embodiments may be applied to any silicon nitride film (e.g., a liner film, an etching stopper film, etc.) present between the transistors Tr1 and Tr2 on the semiconductor substrate 10 and the memory cell array provided above the transistors Tr1 and Tr2. Therefore, it is possible to inhibit hydrogen from being introduced into the transistors Tr1 and Tr2 from the memory cell array and to inhibit the diffusion of hydrogen from the silicon nitride film itself.

### Second Embodiment

FIG. 8 is a cross-sectional view illustrating a configuration example of a semiconductor device 2 according to a second embodiment. The semiconductor device 2 may be a planar transistor used for an LSI or the like. The semiconductor device 2 according to the second embodiment does not have the upper gate electrode 50 made of metal or metal silicide, but has the lower gate electrode 40 made of polysilicon. Therefore, the hard masks 61 and 62 for etching metal or metal silicide are not provided. The other configurations of the second embodiment may be identical to those of the first embodiment. Therefore, the semiconductor device 2 according to the second embodiment does not have the hard masks 61 and 62 on the lower gate electrode 40, but has the sidewall film 70 provided on the side surface of the lower gate electrode 40. The sidewall film 70 may be identical to the sidewall film 70 of the first embodiment. Therefore, it is possible to inhibit hydrogen from being introduced or diffused from the side surface of the lower gate electrode 40.

A method of manufacturing the semiconductor device 2 according to the second embodiment does not form the upper gate electrode 50 illustrated in FIG. 4 and does not use the hard masks 61 and 62. The material of the lower gate electrode 40 is processed by using a photoresist film according to a lithography technology instead of using the hard masks 61 and 62. Therefore, the lower gate electrode 40 is formed. The subsequent manufacturing processes according to the second embodiment may be identical to the manufacturing processes of the first embodiment. Therefore, the semiconductor device 2 according to the second embodiment is completely made.

In the second embodiment, the hard masks 61 and 62 are not provided on the upper surface of the lower gate electrode 40, but the sidewall film 70 is provided on the side surface of the lower gate electrode 40. Therefore, it is possible to inhibit hydrogen from being diffused from the sidewall film 70 and to inhibit hydrogen from being introduced from the side surface of the lower gate electrode 40.

### Third Embodiment

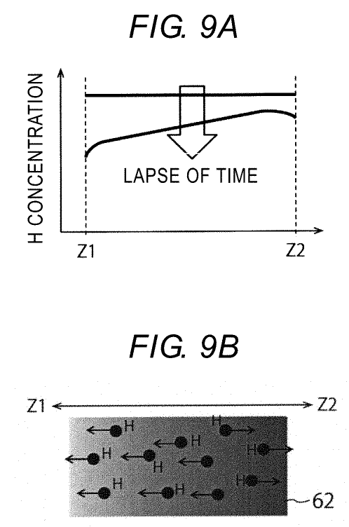

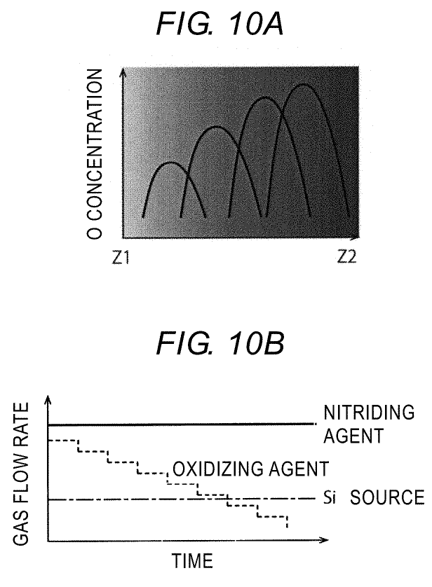

Next, a third embodiment will be described with reference to FIGS. 9A and 9B and FIGS. 10A and 10B. The semiconductor device 1 according to the third embodiment differs from the semiconductor device 1 illustrated in the first embodiment in terms of a composition of the upper hard mask 62. Further, the configurations other than the upper hard mask 62 are identical to those of the first embodiment, and descriptions thereof will be omitted.

The upper hard mask 62 is, for example, a silicon nitride film. For example, in a stacking direction, the upper hard mask 62 according to the present embodiment includes a comparatively large amount of oxygen as the upper hard mask 62 becomes close to the lower hard mask 61, and the upper hard mask 62 includes a comparatively small amount of oxygen as the upper hard mask 62 becomes distant from the lower hard mask 61. Therefore, the upper hard mask 62 has an oxygen concentration gradient in a direction of Z1-Z2 in FIG. 1. Further, in the present embodiment, the upper hard mask 62 has an oxygen concentration gradient, but the element is not limited to oxygen, and for example, the upper hard mask 62 may have a concentration gradient of an element such as nitrogen having higher electronegativity than silicon. Hereinafter, the description will be made based on an example in which the upper hard mask 62 has the oxygen concentration gradient.

Assuming that the stacking direction of the upper hard mask 62 in FIG. 1 is a Z1-Z2 axis, the upper hard mask 62 at the Z2 side is the DCS-SiN(O) film, and the upper hard mask 62 at the Z1 side is the DCS-SiN film. Otherwise, the upper hard mask 62 at the Z2 side is the TCS-SiN(O) film, and the upper hard mask 62 at the Z1 side is the TCS-SiN film. That is, the upper hard mask 62 is configured such that the silicon nitride film including a comparatively larger amount of silicon is provided on an upper portion of the silicon nitride film including a comparatively larger amount of oxygen. In addition, even though the upper hard mask 62 and the lower hard mask 61 are different from each other in terms of the oxygen concentration in the stacking direction, the upper hard mask 62 and the lower hard mask 61 may be films of the same type so as not to greatly change the hydrogen content of the upper hard mask 62 and the lower hard mask 61.

FIGS. 9A and 9B are views illustrating characteristics of the upper hard mask 62 according to the third embodiment. FIG. 9A is a graph illustrating a relationship between a time elapse and a hydrogen concentration in the Z1-Z2 direction with respect to the upper hard mask 62 in FIG. 1. FIG. 9B is a conceptual view illustrating motion of hydrogen that is diffused in accordance with a time elapse. As illustrated in FIG. 9A, a hydrogen concentration of the upper hard mask 62 is decreased in accordance with the time elapse. However, a decreasing rate of the hydrogen concentration is increased toward the Z1 side. The reason is as follows. As described in the first embodiment, the DCS-SiN film includes a larger amount of silicon in comparison with the SiN film including a comparatively large amount of oxygen. For this reason, in the case of the DCS-SiN film, the bonding force of the N-H bond is comparatively low, and hydrogen is easily diffused by a heat treatment or the like. Therefore, the hydrogen concentration of the upper hard mask 62 at the Z1 side, which includes the DCS-SiN film, decreases as the time elapses, but the hydrogen concentration of the upper hard mask 62 at the Z2 side, which has a high oxygen content, does not greatly decrease as the time elapses.

As illustrated in FIG. 9A, in the case of the upper hard mask 62 of the third embodiment, a degree of diffusion of hydrogen varies depending on a position in the stacking direction in accordance with the time elapse. For example, FIG. 9B is a schematic view illustrating a state in which hydrogen is diffused in the upper hard mask 62. Since there is a concentration gradient of oxygen in the upper hard mask 62, hydrogen located, for example, at the Z2 side of the upper hard mask 62 is easily diffused to the Z1 side of the upper hard mask 62. Therefore, the upper hard mask 62 according to the third embodiment has the same effect as that of the first embodiment, and enables hydrogen to be diffused to the Z1 side where the transistors Tr1 and Tr2 are not provided. Therefore, it is possible to further inhibit deterioration in characteristics of the transistors Tr1 and Tr2.

Next, a method of manufacturing the semiconductor device 1 according to the third embodiment will be described with reference to FIGS. 10A and 10B. Further, the manufacturing processes other than the process of manufacturing the upper hard mask 62 are identical to those of the first embodiment, and descriptions thereof will be omitted.

Similar to the first embodiment, the upper hard mask 62 of the third embodiment may be formed by the ion implantation method or the LP-CVD method.

In the case in which the upper hard mask 62 is formed by the ion implantation, the silicon nitride film, which is to be the hard masks 61 and 62, is formed first on the material of the upper gate electrode 50 by using the LP-CVD method or the PE-CVD method described in the first embodiment. For example, the silicon nitride film may be formed by adding nitride gas such as ammonia (NH₃) to a silicon source such as silane (SiH₄), dichlorosilane (SiH₂Cl₂), or tetrachlorosilane (SiCl₄) under an ambience of about 650° C. to about 750° C. Thereafter, oxygen is implanted into the silicon nitride film by the ion implantation. For example, as illustrated in FIG. 10A, oxygen is implanted into the silicon nitride film multiple times by the ion implantation in the stacking direction from the Z2 side to the Z1 side. In this case, the oxygen ions are implanted while a dose amount and acceleration energy thereof are changed. Therefore, as illustrated in FIG. 10A, the upper hard mask 62 has an oxygen concentration gradient so that the oxygen concentration is gradually increased from the Z1 side to the Z2 side.

In the case in which the silicon nitride film is formed by the LP-CVD method, at the time of forming the lower hard mask 61, the silicon nitride film is formed by, for example, adding nitride gas such as ammonia (NH₃) into a silicon source such as tetrachlorosilane (SiCl₄). Thereafter, at the time of forming the upper hard mask 62, the silicon nitride film may be formed by, for example, adding nitride gas such as ammonia (NH₃) and oxidative gas such as a minuscule amount of oxygen (O₂) or dinitrogen monoxide (N₂O) into a silicon source such as tetrachlorosilane (SiCl₄). For example, as illustrated in FIG. 10B, a flow rate of the oxidative gas to be added during the film forming process may be decreased in accordance with the time elapse. Therefore, the upper hard mask 62 has an oxygen concentration gradient so that the oxygen concentration is gradually increased from the Z1 side to the Z2 side.

With the aforementioned method, the upper hard mask 62 of the third embodiment is formed.

According to the semiconductor device 1 according to the third embodiment, the upper hard mask 62 including the silicon nitride film further includes an element having electronegativity higher than electronegativity of silicon and has a concentration gradient of the element in the stacking direction. That is, the concentration of the element is increased toward the transistors Tr1 and Tr2 (Z2 side), and the concentration thereof is decreased away from the transistors Tr1 and Tr2. Hydrogen is easily diffused in a direction in which the concentration of the element is decreased, and hydrogen is moved away from the transistors Tr1 and Tr2, and as a result, it is possible to inhibit deterioration in characteristics of the transistors Tr1 and Tr2.

The third embodiment is described as being applied to the semiconductor device 1 of the first embodiment, but the third embodiment may be applied to the semiconductor device 2 of the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
an insulating film provided on the substrate;
an electrode provided on the insulating film;
a first silicon nitride film provided on an upper surface of the electrode; and
a second silicon nitride film provided on the first silicon nitride film and having a higher oxygen concentration than the first silicon nitride film.

2. The semiconductor device according to claim 1, further comprising: a third silicon nitride film provided on a side surface of the electrode and having a higher oxygen concentration than the first silicon nitride film.

3. The semiconductor device according to claim 2, wherein the third silicon nitride film has a same oxygen concentration as the second silicon nitride film.

4. The semiconductor device according to claim 1, wherein at least an upper portion of the electrode is made of either a metal or metal silicide.

5. The semiconductor device according to claim 4, wherein a lower portion of the electrode is made of a different material than that of the upper portion.

6. The semiconductor device according to claim 5, wherein the lower portion of the electrode is made of polysilicon.

7. The semiconductor device according to claim 5, further comprising a barrier metal disposed between the lower portion and the upper portion.

8. The semiconductor device according to claim 1, further comprising: a source layer and a drain layer provided on a surface of the substrate at both sides of the electrode, wherein each of the electrode, the source layer, and the drain layer includes a p-type impurity.

9. The semiconductor device according to claim 1, wherein the second silicon nitride film includes an element having higher electronegativity than silicon, a concentration of the element in the second silicon nitride film decreases with a distance from the first silicon nitride film.

10. The semiconductor device according to claim 9, wherein the element is oxygen.

11. A semiconductor device comprising:
a substrate;
an insulating film provided on the semiconductor substrate;
an electrode provided on the insulating film; and
a silicon nitride film provided on at least one of an upper surface or a side surface of the electrode,
wherein the silicon nitride film has an oxygen concentration of 1% to 10%.

12. The semiconductor device according to claim 11, wherein the silicon nitride film is provided only on the side surface of the electrode.

13. A method of manufacturing a semiconductor device, the method comprising:
forming an insulating film on a substrate;
forming a material of an electrode on the insulating film;
forming a silicon nitride film, into which oxygen is introduced, as a mask material on the material of the electrode;
processing the mask material into a pattern of the electrode; and
processing the electrode using the mask material as a mask.

14. The method according to claim 13, further comprising forming an interlayer insulating film directly on the electrode, wherein the electrode is formed of a single material.

15. The method according to claim 13, wherein the forming the silicon nitride film, into which oxygen is introduced, comprises forming the silicon nitride film and then implanting oxygen into the silicon nitride film.

16. The method according to claim 13, wherein the forming the silicon nitride film, into which oxygen is introduced, comprises introducing oxygen while forming the silicon nitride film.

17. The method according to claim 13, wherein the introducing oxygen while forming the silicon nitride film comprises introducing an oxidative gas.

18. The method according to claim 13, wherein the silicon nitride film is formed using tetrachlorosilane.

19. The method according to claim 13, wherein the silicon nitride film is formed using dichlorosilane.

20. The method according to claim 13, further comprising:
forming the silicon nitride film, into which oxygen is introduced, as a sidewall film, on the processed electrode; and
etching the sidewall film such that the sidewall film remains on a side surface of the electrode.
